(19) United States
(12) Patent Application Publication
(10) Pub. No.: US 2018/0040589 A1
(43) Pub. Date: Feb. 8, 2018

(54) MICROELECTRONIC PACKAGES AND ASSEMBLIES WITH REPEATERS

(71) Applicant: Invensas Corporation, San Jose, CA (US)

(72) Inventors: Shaowu Huang, Sunnyvale, CA (US); Zhuowen Sun, Campbell, CA (US); Javier A. Delacruz, Santa Clara, CA (US); Belgacem Haba, Saratoga, CA (US)

(21) Appl. No.: 15/227,361

(22) Filed: Aug. 3, 2016

(51) Int. Cl. H01L 25/065; H01L 23/538; G11C 5/06; H01L 25/10

(52) U.S. Cl. CPC H01L 25/0657; H01L 25/105; H01L 23/5386; G11C 5/06; H01L 2225/06562; H01L 2225/06506; H01L 2225/0651; H01L 2225/1035; H01L 2225/1064; H01L 2225/06551

(57) ABSTRACT

A microelectronic assembly includes a circuit panel having a plurality of first contacts at a major surface thereof. One or more microelectronic packages comprise a plurality of microelectronic elements, the one or more packages having terminals electrically coupled with the first contacts, wherein each package includes at least one microelectronic element having a face, and element contacts at the face which are electrically coupled with the plurality of terminals. A repeater (redriver or retimer) assembly is configured to condition one or more signals received from a memory channel control element including one or more signals selected from: an address signal, a command signal, or a data signal, such that the plurality of the microelectronic elements are coupled to the at least one repeater assembly to receive the conditioned signals.

### BACKGROUND OF THE INVENTION

### Technical Field

The subject matter of this application relates to microelectronic packages and assemblies in which a plurality of microelectronic packages are stacked with one another and electrically interconnected with a circuit panel.

### Description of the Related Art

Semiconductor dies or chips are flat bodies with contacts disposed on the front surface that are connected to the internal electrical circuitry of the chip itself. Semiconductor chips are typically packaged with substrates to form microelectronic packages having terminals that are electrically connected to the chip contacts. The package may then be connected to test equipment to determine whether the packaged device conforms to a desired performance standard. Once tested, the package may be connected to a larger circuit, e.g., a circuit in an electronic product such as a computer, tablet, smartphone or other mobile device.

In order to save space certain conventional designs have stacked multiple microelectronic elements or semiconductor chips within a package. This allows the package to occupy a surface area on a substrate that is less than the total surface area of the chips in the stack. However, conventional stacked packages have disadvantages of complexity, cost, thickness and testability.

In spite of the above advances, there remains a need for improved stacked packages and especially stacked chip packages which incorporate multiple chips for certain types of memory, e.g., flash memory. There is a need for such packages and assemblies which are reliable, thin, testable and that are economical to manufacture.

### BRIEF DESCRIPTION OF THE SEVERAL VIEWS OF THE DRAWINGS

FIGS. 1 and 2 depict microelectronic packages and their interconnections with a circuit panel to form microelectronic assemblies.

FIG. 3 illustrates a microelectronic assembly in accordance with an embodiment of the invention.

FIG. 4 illustrates a microelectronic assembly in accordance with an embodiment of the invention.

FIG. 5 illustrates a microelectronic assembly in accordance with an embodiment of the invention.

FIG. 6 illustrates a microelectronic assembly in accordance with an embodiment of the invention.

FIG. 7 illustrates a microelectronic assembly in accordance with an embodiment of the invention.

FIG. 8 illustrates a microelectronic assembly in accordance with an embodiment of the invention.

FIG. 9 illustrates a microelectronic assembly in accordance with an embodiment of the invention.

FIG. 10 illustrates a microelectronic assembly in accordance with an embodiment of the invention.

FIG. 11 illustrates a microelectronic assembly in accordance with an embodiment of the invention.

FIG. 12 illustrates a microelectronic assembly in accordance with an embodiment of the invention.

FIG. 13 illustrates a microelectronic assembly in accordance with an embodiment of the invention.

### DESCRIPTION OF THE INVENTION

Computing systems need to provide access to data and instructions from a memory storage array during execution of a program by a processor (e.g., microprocessor or other form of central processing unit (“CPU”)). Such systems typically include a processor which can function as a memory channel control element, or may include a processor having a memory channel control element incorporated thereon, or a stand-alone memory channel control element which communicates with the processor to store and retrieve data and/or instructions from microelectronic elements separate from the processor which have memory storage arrays thereon. The memory control element typically controls traffic, i.e., data, address, clock and command signals on a signaling bus between the memory storage array and the CPU. In some cases, instructions can be stored to the one or more memory storage arrays and retrieved from the one or more memory storage arrays for execution by the processor.

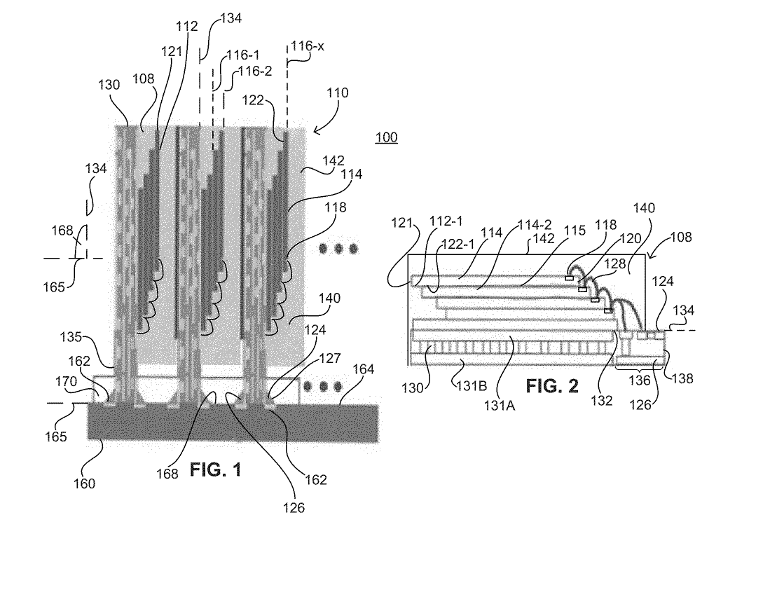

Traditionally, microelectronic elements are assembled together in microelectronic packages which are surface-mounted to a major surface of a circuit panel, wherein planes defined by major surfaces of the microelectronic elements, e.g., semiconductor chips, are oriented in parallel with the major surface of the circuit panel. However, in a microelectronic assembly 100 as seen, for example, in FIGS. 1 and 2, a circuit panel has a plurality of stacked microelectronic packages mounted thereto each having a plurality of microelectronic elements therein, wherein a plane defined by a major surface of each microelectronic element is oriented in directions that are not parallel to the major surface of the circuit panel to which the microelectronic element is coupled. In a particular example, the planes of microelectronic elements in the electronic system can be oriented in a direction that is orthogonal, i.e., perpendicular, to the major surface of the circuit panel.

Such non-parallel or orthogonal orientations permit a relatively large number of microelectronic elements to be accommodated within a given area of the major surface of the circuit panel, the microelectronic elements being electrically coupled with conductors on the circuit panel. However, increasing the number of microelectronic elements coupled to a signal bus can exacerbate loading on the signal bus when all other factors remain the same. A large number of microelectronic elements coupled to the same bus controlled by a single memory channel control element can cause adverse (multi-drop) loading effects to increase, among which may include any or all of the following: increased intersymbol interference, lowered signal amplitudes, increased rise time and increased fall time, and reduced eye width and reduced eye height. As a consequence, the speed at which signals can be transmitted in an assembly with increased loading tends to fall. The decrease in speed can be substantial, i.e., 50% or more of the speed in cases where loading on a signaling bus is increased by a factor or four or eight, for example.

In an embodiment of the invention provided herein, the increased loading effects can be mitigated by conditioning, e.g., amplifying signals on the signaling bus at points between the memory channel control element and the microelectronic elements. In one embodiment, amplification can be performed in the analog domain, which in some cases can permit a type of circuitry required to perform the conditioning to be relatively simple, and in some cases, relatively compact in terms of the external volume required by the conditioning circuitry. The conditioning circuitry, e.g., analog amplifying circuitry in accordance with such embodiment, can be referred to as a “redriver assembly” which includes a plurality of individual “redrivers”. A redriver typically contains no clock data recovery (CDR), and amplifies the signal magnitude without performing retiming functionality. Each such redriver is electrically coupled to a signaling path of a signaling bus at a point remote from the memory channel control element at a first side of the redriver, and at a second side of the redriver opposite the first side, the redriver is coupled to a signaling path to which a microelectronic element is coupled. In one example, some of the redrivers are each configured to amplify, in the analog domain, a signal received from the memory channel control element and output the amplified signal to a microelectronic element. In such example, others of the redrivers may each be configured to amplify, in the analog domain, a signal received from a microelectronic element and output the amplified signal to the memory channel control element.

In variations of any of the above-described microelectronic assemblies, the repeater assembly takes the form of a “retimer” assembly having a plurality of retimers thereon in the above-described embodiments, where each retimer of the retimer assembly takes the place of each redriver of the redriver assembly. A retimer usually contains CDR, and functions differently from a redriver, in that the retimer receives and regenerates the signal anew that is to be driven at the input of the retimer. The retimer can be considered a buffer or isolator device between a generator of a signal, e.g., the memory channel control element and a consumer of that signal, which in some cases can be the microelectronic element having a memory storage array thereon. As such, the retimer “isolates” the output from the input through retransmitting signals with newly generated amplitudes and phases. The redriver and the retimer are two types of repeaters that the repeater assembly may include.

In one embodiment disclosed, a microelectronic assembly includes a circuit panel having a plurality of first contacts at a major surface thereof. One or more microelectronic packages comprise a plurality of microelectronic elements, the one or more packages having terminals electrically coupled with the first contacts, wherein each package includes at least one microelectronic element having a face, and element contacts at the face which are electrically coupled with the plurality of terminals. A repeater assembly is configured to condition one or more signals received from a memory channel control element including one or more signals selected from: an address signal, a command signal, or a data signal, such that the plurality of the microelectronic elements are coupled to the at least one repeater assembly to receive the conditioned signals. Conditioning signals by the repeater assembly improves one or more of: signal strength or a signal-to-noise ratio of the signals at the respective inputs to the microelectronic elements, or at the inputs to the memory channel control element, or at both the inputs to the microelectronic elements and at the inputs to the memory channel control element. In one example, the repeater assembly may additionally be configured with terminating circuitry, such that signaling paths extending from the repeater assembly to microelectronic elements or microelectronic packages of the assembly which contain them have terminations appropriate for the signaling paths between the repeater assembly and the circuit panel. In this way, signal reflections along paths between the microelectronic elements and the memory channel control element can be addressed and reduced, thereby improving signal-to-noise ratio in the signals transmitted between the memory channel control element and the microelectronic elements. In any of these examples, other aspects of signal quality, such as rise time, fall time and eye width/height may be improved and intersymbol interference may be reduced.

FIG. 1 illustrates components of a microelectronic assembly 100 in accordance with an embodiment of the invention. As seen in FIG. 1, microelectronic assembly 100 includes a package stack 110 which includes a plurality of microelectronic packages 108. Each microelectronic package 108, in turn, includes one or more microelectronic elements 112. Microelectronic assembly 100 and other microelectronic assemblies disclosed or referenced herein can provide enhanced storage density which can be advantageously provided in various computing systems which can be small, medium, or large-scale computing systems, or which may be advantageously used in data centers, among which are enterprise systems, government systems, hosted systems, search engine systems, cloud storage, or other large-scale data centers.

Each package may include a single microelectronic element 112, or in the particular case seen in FIGS. 1-2, a plurality of stacked microelectronic elements. In one example, microelectronic element 112 may be a bare semiconductor chip, or may be a semiconductor chip having contacts at a front face thereof and additional electrically conductive features thereon which overlie the front face and are coupled with the contacts.

As used in this disclosure with reference to a dielectric region or a dielectric structure of a component, e.g., circuit structure, interposer, microelectronic element, capacitor, voltage regulator, circuit panel, substrate, etc., a statement that an electrically conductive element is “at” a surface of the dielectric region or component indicates that, when the surface is not covered or assembled with any other element, the electrically conductive element is available for contact with a theoretical point moving in a direction perpendicular to that surface of the dielectric region from outside the dielectric region or component. Thus, a terminal or other conductive element which is at a surface of a dielectric region may project from such surface; may be flush with such surface; or may be recessed relative to such surface in a hole or depression in the dielectric region.

Each microelectronic element 112 has a front surface 114 defining a respective plane 116-x of a plurality of planes 116-1, 116-2, etc. Each microelectronic element 112 may have a plurality of contacts 118 at a front surface thereof at or near a peripheral edge surface 120 of the chip, with a rear surface 122 opposite the front surface, and the interconnect edge surface 120 extending between the front and rear surfaces. Commonly available flash memory semiconductor chips, such as the NAND and NOR type flash memory chips mentioned below, typically have their chip contacts disposed at the front surface near a single peripheral edge surface 120 of the semiconductor chip. Although the front surfaces of each of the chips in the package stack are shown all oriented in the same direction in FIGS. 1 and 2, the front surfaces of one or more of the chips in the package stack can be oriented in the opposite direction such that portions of the front surfaces of at least two of the chips which are adjacent one another would either face one another or would face in opposite directions away from one another. As seen in FIG. 2, a second peripheral edge surface 121 of each chip is opposite from the peripheral edge surface 120.

As best seen in FIG. 2, each stack of microelectronic elements 112 may include a dielectric region 115 that extends between the rear surface 122-1 of a first chip 112-1 and a front surface 114-2 of a second chip 112-2 adjacent to the first chip in a microelectronic package. Such dielectric regions are disposed between adjacent surfaces of other chips in the package stack depicted in FIG. 2. The dielectric region may include one or more adhesive layers or other dielectric material. Typically, the dielectric region includes at least adhesive layers coupled to each of the opposed front or rear surfaces of adjacent chips in the package stack. In one embodiment, the dielectric region 115 includes one or more layers of epoxy, elastomer, polyimide, parylene, or other polymeric material.

In one example, each of the microelectronic elements includes one or more memory storage arrays, which may include a particular memory type such as nonvolatile memory. Nonvolatile memory can be implemented in a variety of technologies some of which include memory cells that incorporate floating gates, such as, for example, flash memory, and others which include memory cells which operate based on magnetic polarities. Flash memory chips are currently in widespread use as solid state storage as an alternative to magnetic fixed disk drives for computing and mobile devices. Flash memory chips are also commonly used in portable and readily interchangeable memory drives and cards, such as Universal Serial Bus (USB) memory drives, and memory cards such as Secure Digital or SD cards, microSD cards (trademarks or registered trademarks of SD-3C), compact flash or CF card and the like. Flash memory chips typically have NAND or NOR type devices therein; NAND type devices are common. Other examples of microelectronic elements 112 include one or more of DRAM, microprocessor or controller chips or combinations thereof. Each semiconductor chip may be implemented in one of various semiconductor materials such as silicon, germanium, and gallium arsenide or one or more other Group III-V semiconductor compounds or Group II-VI semiconductor compounds, etc. The microelectronic elements 112 in one or more microelectronic packages 108 and in one or more “package stacks” 110 may be a combination of different chip functionalities as described above and may comprise a combination of various different semiconductor materials as described above. In one embodiment, a microelectronic element may have a greater number of active devices for providing memory storage array function than for any other function.

In one embodiment, each package 108 of the package stack 110 includes a dielectric element 130 having a major surface 132 which defines a plane 134. The dielectric element 130 may have one or multiple layers of dielectric material and one or multiple electrically conductive layers thereon. The dielectric element 130 can be formed of various materials, which may or may not include a polymeric component, and may or may not include an inorganic component. Alternatively, the substrate may be wholly or essentially polymeric or may be wholly or essentially inorganic. In various non-limiting examples, the dielectric element can be formed of a composite material such as glass-reinforced epoxy, e.g., FR-4, or glass or ceramic material.

A plurality of electrically conductive package contacts 124, 126 are disposed at an interconnect region 136 of the dielectric element 130 adjacent an interconnect edge 138 of the dielectric element 130. In one example seen in FIGS. 1 and 2, package contacts 124 are at a first major surface 132 of the dielectric element 130, and package contacts 126 are at a second major surface 135 of the dielectric element opposite from the first major surface 132. A thermally conductive plane, e.g., 131A, 131B, may be disposed at one or both of the first or second major surfaces 132, 135.

Element contacts 118 at front surfaces 114 of each microelectronic element of the package 108 are electrically coupled with the package contacts 124, 126 such as through leads 128 which may include, for example, wire bonds coupled to the microelectronic elements 112 arranged in an offset or staggered arrangement such as seen in FIG. 2. Alternatively, the electrical connections between the package contacts 124, 126 and the element contacts 118 can include a curable electrically conductive material, such as, for example, an electrically conductive material in a polymer matrix or electrically conductive ink deposited as drops, droplets or lines of the conductive material onto the package contacts, element contacts, and the areas in between. Alternatively, lines of conductive material can be formed by blanket depositing such material and then removing the material between laterally adjacent contacts on the same microelectronic subassembly or package 108, and between adjacent portions of the leadframe on the same microelectronic package 108. In one example, the electrically conductive material can be such as described in U.S. Pat. No. 8,178,978 to McElrea et al., the disclosure of which is incorporated herein by reference. Alternatively, electrical connections between the package contacts and the element contacts can include a metal plated onto and in-between the package contacts 124, 126 and the element contacts 118.

Each package contact 124, 126 may extend to the interconnect edge 138 of the package 108 in an interconnect region 136 which may extend from a peripheral edge or “remote surface” of the respective package 108. In some cases, a dielectric region or insulating encapsulant region 140 may contact the element contacts 118 at the front surface of each microelectronic element 112 and may overlie a portion of the major surface 132 of the dielectric element 130. In one example, as seen in FIGS. 1 and 2, the encapsulant region 140 has a major surface 142 which is substantially parallel to the major surface 132 of the dielectric element. In particular cases, the encapsulant region of a given package can extend laterally outward beyond two or more edge surfaces of the microelectronic elements 112 in the package to corresponding remote surfaces of the package which are spaced apart from the edge surfaces of the microelectronic elements. In an example, the dielectric region 140 may be or may include a molded dielectric region. In one example, the dielectric region may comprise a polymeric dielectric material, or alternatively a polymeric dielectric material with a filler therein which may have a lower coefficient of thermal expansion than the polymeric material. In some examples, the filler may include particles, flakes or a mesh or scaffold of an inorganic material such as a glass, quartz, ceramic or semiconductor material, among others.

As mentioned above, all package interconnects of a package typically are available for connection at an interconnect region adjacent the same interconnect edge 138 of the package. As further seen in FIG. 1, the package contacts 124, 126 of a stacked microelectronic package 108 in the package stack, in turn, are electrically coupled to respective panel contacts 162 at a major surface 164 of a circuit panel 160 through an electrically conductive material 127. It will be appreciated that the substantially parallel planes 134, 116 defined by the major surface and front surfaces of the dielectric elements and microelectronic elements are oriented at a substantial angle 168 to a plane 165 defined by the major surface 164 of the circuit panel. In one example, the angle 168 can be greater than or equal to or 20 degrees. In another example, the angle 168 can be greater than or equal to or 30 degrees. In another example, the angle 168 can be greater than or equal to or 45 degrees. In yet another example, the angle 168 can be greater than or equal to or 90 degrees, or in some cases, can be greater than or equal to 120 degrees. FIG. 1 shows an example in which the angle 168 is at or substantially equal to 90 degrees, such that the planes 116 of the microelectronic elements are oriented in a direction which is substantially orthogonal to the plane 165 defined by the major surface 164 of the circuit panel 160. In this case, the major surface 164 of the circuit panel faces edge surfaces 120 of each microelectronic element. An insulating layer 170, which in some cases may be a mechanically reinforcing layer such as an underfill, may be applied surrounding the electrical connections between the package contacts 124, 126 and the panel contacts 162. In some cases, the insulating layer 170 can mechanically reinforce or stiffen such electrical connections and may help those electrical connections withstand stresses due to differential thermal expansion between the packages 108 and the circuit panel 130. In one example, the insulating layer can be a “board level underfill layer.”

In particular examples, the electrically conductive material 127 may be conductive masses, conductive pillars, stud bumps or other suitable electrically conductive material may be used to electrically connect each of the package contacts 124, 126 with a corresponding panel contact 162. Here, the conductive material 127 can be in form of electrically conductive bumps such as masses of solder, tin, indium or eutectic material, or drops or droplets of electrically conductive polymer material or electrically conductive ink on surfaces of the panel contacts 162 and contacting the corresponding package contacts 124, 126. In one example, the electrically conductive material 127 may be applied to the panel contacts 162, the package contacts 124, 126, or both the package contacts and the panel contacts through a transfer mold of solder bumps, balls or features, or application of solder balls, for example, or may alternatively be deposited on the substrate contacts by plating or depositing a metal or other conductive material. Alternatively, the electrically conductive material 127 can be applied by depositing one of the above-mentioned electrically conductive polymer or electrically conductive ink or any other electrically conductive materials. In one example, the electrically conductive material may be as disclosed in the incorporated U.S. Pat. No. 8,178,978.

In one example, the circuit panel can be a motherboard. In another example, the circuit panel 160 can be a daughter board, module board or other board or circuit panel configured for electrical connection within a system which includes the microelectronic package stack 110 and circuit panel. The panel contacts 162 can be configured for surface mounting to another component which can be a card, tray, motherboard, etc., such as via a land grid array (LGA), ball grid array (BGA), or other technique. As in the case of the dielectric element 130, the circuit panel 160 may include a dielectric element or other substrate which may have one or multiple layers of dielectric material and one or multiple electrically conductive layers thereon. The circuit panel 160 can be formed of various materials, which may or may not include a polymeric component, and may or may not include an inorganic component. Alternatively, the circuit panel may be wholly or essentially polymeric or may be wholly or essentially inorganic. In various non-limiting examples, the support element can be formed of a composite material such as glass-reinforced epoxy, e.g., FR-4, a semiconductor material, e.g., Si or GaAs, or glass or ceramic material.

In a variation of the microelectronic assembly seen in FIGS. 1 and 2, each microelectronic element may have chip terminals electrically coupled to or extending from the contacts thereof, such as shown and disclosed in U.S. application Ser. No. 15/208,985, the disclosure of which is incorporated by reference herein. In another variation, each microelectronic element of a microelectronic package may be electrically coupled with package contacts of each package through leadframe interconnects, such as shown and disclosed in one or more of U.S. application Ser. Nos. 15/209,034, 14/883,864 the disclosures of which are incorporated by reference herein.

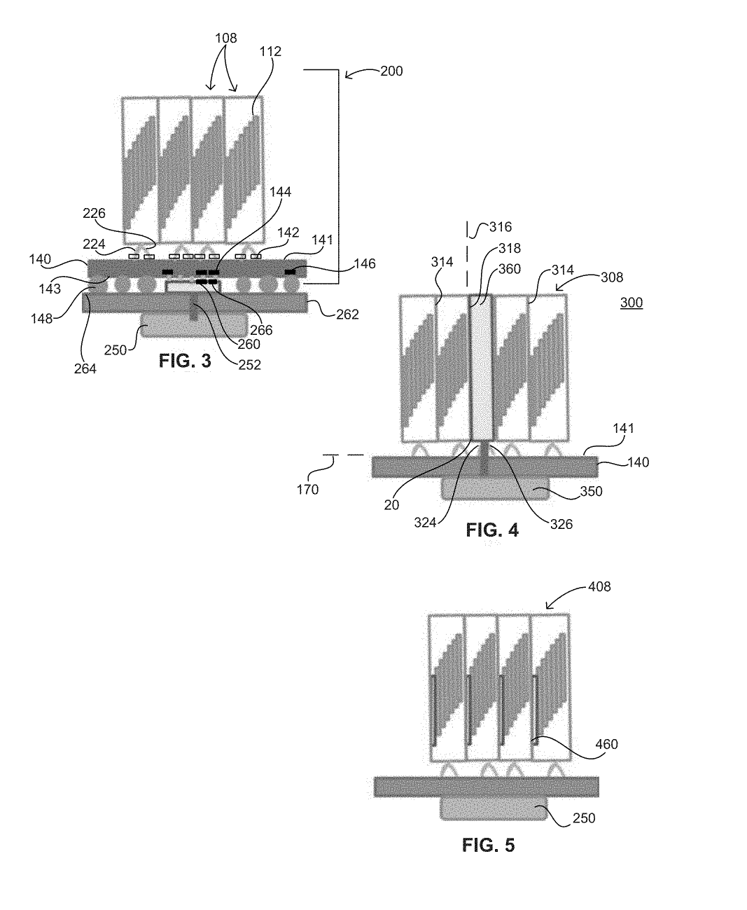

Referring now to FIG. 3, a microelectronic assembly 200 in accordance with an embodiment of the invention includes a plurality of microelectronic packages 108 each as discussed above relative to FIGS. 1 and 2, or otherwise as shown and disclosed in one of the applications incorporated by reference herein. As further seen in FIG. 3, the plurality of microelectronic packages 108 are electrically interconnected with first contacts 142 at a first surface 141 of a circuit panel 140 through package contacts 224, 226 at the edge surfaces of the packages 108, for example. As further shown in FIG. 3, microelectronic assembly includes a repeater assembly 260 having a major surface 264 which overlies a second surface 143 of the circuit panel 140. In one example, the repeater assembly may be electrically interconnected with second contacts 144 at the second surface 143 such as through electrically conductive bumps which face corresponding contacts 266 of the repeater assembly. As further seen in FIG. 3, a memory channel control element 250 can be electrically coupled with the repeater assembly 260 through a plurality of relatively short bus conductors 252. In one example, repeater assembly can be an integrated circuit having a plurality of individual repeaters, each repeater constructed of devices comprising at least active electronic devices which are configured to amplify signals received at inputs thereof and provide the same to outputs of the repeater assembly. In one example, the repeater assembly amplifies uni-directional signals transmitted in a direction from the memory controller element to a microelectronic element of the assembly. In another example, one or more repeaters are coupled to a bi-directional input-output pair of contacts on the repeater assembly such that the one or more repeaters amplifies bi-directional signals as transmitted in a direction from the memory channel control element to a microelectronic element and as transmitted in a direction from a microelectronic element to the memory channel control element.

Memory channel control element 250 may only be capable of driving signals to a limited number of receivers thereof. In one example, the control element 250 may only be capable of driving signals to eight receivers of the signals. Thus, if the memory channel control element 250 were coupled directly to the microelectronic elements 112, the control element 250 might only be capable of driving signals to eight microelectronic elements 112. However, with the addition of the repeater assembly 260, each repeater of the repeater assembly 260 can be electrically coupled with the contacts of a plurality of microelectronic elements 112. Thus, in one example, each repeater of the repeater assembly can be electrically coupled in parallel with the contacts of two microelectronic elements 112 of the assembly, and in that case, increase the number of microelectronic elements 112 to which signals can be driven from the memory channel control element 250 by a factor of two, such that one memory channel control element 260 is capable of driving signals to sixteen microelectronic elements. In other examples, each repeater of the repeater assembly can be electrically coupled in parallel with the contacts of four microelectronic elements 112, and in such case, increase the number of microelectronic elements 112 to which signals can be driven from the memory channel control element 250 by a factor of four. In still other examples, each repeater of the repeater assembly can be electrically coupled in parallel with the contacts of eight or sixteen microelectronic elements 112, and in such case, increase the number of microelectronic elements 112 to which signals can be driven from the memory channel control element 250 by a factor of eight, or by a factor of sixteen. In such examples the microelectronic assembly with the memory channel control element 250 and repeater assembly thereon are configured to drive signals to 64 or 128 microelectronic elements, respectively.

In a particular implementation as seen in FIG. 3, the microelectronic assembly 200 has a plurality of terminals 146 at a second surface 143 of the circuit panel 140, which terminals have a ball grid array (“BGA”) terminals 146 or land grid array (“LGA”) connections through conductive masses 148 to a second circuit panel 262. In one example, the memory channel control element 250 can be mounted to a major surface of the second circuit panel 262, such as a major surface of the second circuit panel 262 opposite from the first circuit panel, wherein a major surface of the memory channel control element overlies and is parallel to the major surface of the first circuit panel 140.

With further reference to FIG. 9, electrically conductive paths between the repeater assembly 260 and the microelectronic packages can be provided as follows. As shown schematically via the upwardly-extending arrows in FIG. 9, electrically conductive paths can extend from repeaters in the repeater assembly 260 to respective sets of first panel contacts 142 to which the terminals 224, 226 of each individual microelectronic package 108 are coupled.

FIG. 4 illustrates a microelectronic assembly in accordance with a variation of the embodiment seen in FIG. 3, in which the repeater assembly 360 has a surface 320 proximate the major surface 141 of the circuit panel in a state in which the repeater assembly is mounted to the circuit panel 140. A plane 316 defined by the major surface 318 of the repeater assembly is oriented at an angle relative to the plane 170 defined by the major surface 141 of the circuit panel, such that planes 316, 170 are not parallel with one another, and can be at a substantial angle, or in some cases orthogonal to one another. In such case, the repeater assembly can be electrically coupled with the memory channel control element through terminals 324, 326 of the repeater assembly 360.

In a particular variation of the microelectronic assembly 300 seen in FIG. 4, the total quantity or number of terminals 224, 226 at the edge surfaces of the microelectronic packages 108 which face the circuit panel 140 can in some cases be reduced, such that the plurality of packages 308 considered collectively have a reduced number of terminals or “reduced pin count” relative to the number of terminals 224, 226 at the edge surfaces in a microelectronic assembly such as that shown in the microelectronic assembly of FIG. 3. In such variation repeater assembly 360 can distribute signals that it amplifies to the microelectronic packages 308 through sets of contacts at major surfaces 314 of the packages 308, for example.

As seen in FIG. 5, in another variation, a repeater assembly 460 is included in an electrically coupled within each of a plurality of microelectronic packages 408 which include a plurality of microelectronic elements. In one embodiment, each microelectronic package 408 includes a plurality of microelectronic elements, for example, two, four or eight microelectronic elements and a repeater assembly which amplifies signals for at least one of transmitting the signals to the microelectronic elements, or transmitting the signals to the memory channel control element 250. One advantage of placing the repeater assembly at a level of microelectronic package 408 is that of improved yield in case of a defective repeater assembly. If a repeater assembly within a package 408 as seen in FIG. 5 is defective, the defect typically will only cause one microelectronic package to be defective. This is because the defect in the repeater assembly can be fully addressed by replacing the microelectronic package in which the repeater assembly is incorporated, rather than having to replace a greater number of packages and possibly other components, e.g., a circuit panel among others.

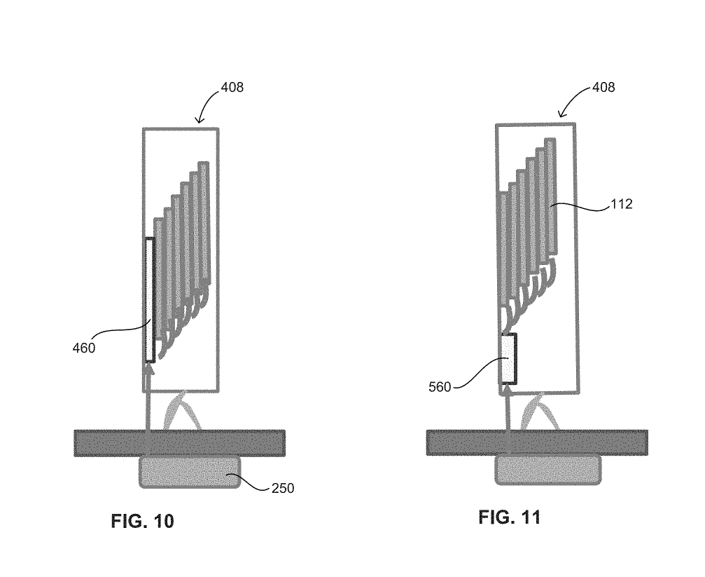

As further seen in FIG. 10, the repeater assembly in each microelectronic package 408 can be coupled to communicate with the memory channel control element 250, and, in turn, transmit and/or receive signals from each of a plurality of stacked microelectronic elements of the package 408 which are stacked with the repeater assembly, e.g., atop the repeater assembly 460.

In a variation thereof, as seen in FIG. 11, a repeater assembly 560 can be horizontally offset within the microelectronic package 408 from the microelectronic elements 112 therein. in such case, electrical connections between the repeater assembly and the microelectronic elements may be provided either directly by conductive paths, e.g., thin flexible wires or traces between the repeater assembly and the microelectronic elements, or otherwise by a stair step arrangement of conductive paths extending upwardly along the stair step offset stack of microelectronic elements shown in FIG. 11.

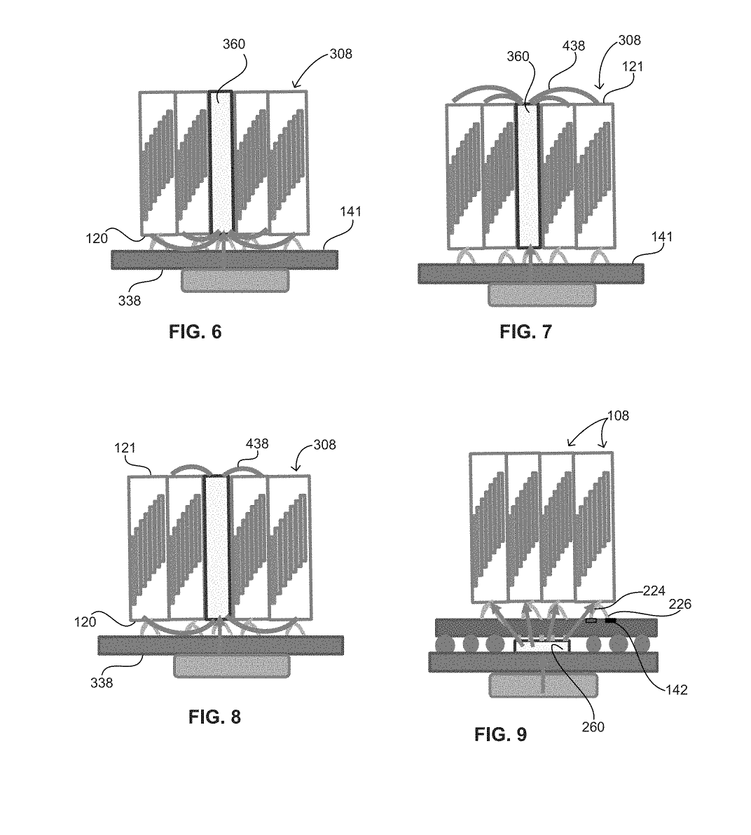

Referring now to FIG. 6, a repeater assembly can be an element having a major surface parallel to major surfaces of a plurality of microelectronic packages 308 such that the major surface of the repeater assembly 360 is oriented at an angle relative to the major surface 141 of the circuit panel, i.e., not parallel to major surface 141 and repeater assembly 360 overlies the same major surface 141 of the circuit panel which the one or more microelectronic packages overlie. In one example, the repeater assembly 360 outputs the amplified signals directly to each microelectronic package 308 in the microelectronic assembly through conductors 338 extending from the repeater assembly to each microelectronic package. In one embodiment, the conductive paths can be electrically conductive traces such as traces made of metal or a flowable electrically conductive material which extend in directions generally parallel to edge surfaces 120 of the microelectronic packages and the major surface 141 of the circuit panel. In another embodiment, the electrically conductive paths can include thin flexible wires such as, for example, bonding wires 338 which extend from the repeater assembly along an edge surface 120 of an individual microelectronic package 308 to each microelectronic package.

Referring now to FIG. 7, in a variation of the embodiment of FIG. 6, conductive paths 438 which electrically couple the repeater assembly 360 to individual microelectronic packages 308 can be provided at locations proximate to, e.g., nearer to or adjacent to remote edge surfaces 121 of the microelectronic packages which face away from the major surface 141 of the circuit panel. In other examples, the conductive paths may include conductors, e.g., electrically conductive traces or any of the above-described conductors extending proximate to and in directions generally parallel to and any of the edge surfaces of the microelectronic packages 308.

In another variation as seen in FIG. 8, conductors 338 which electrically couple the repeater assembly 360 to individual microelectronic packages 308 may extend proximate to edge surfaces 120 which face the circuit panel, and some conductors 438 may also extend proximate to remote edge surfaces 121 of the microelectronic packages which face away from the major surface 141 of the circuit panel.

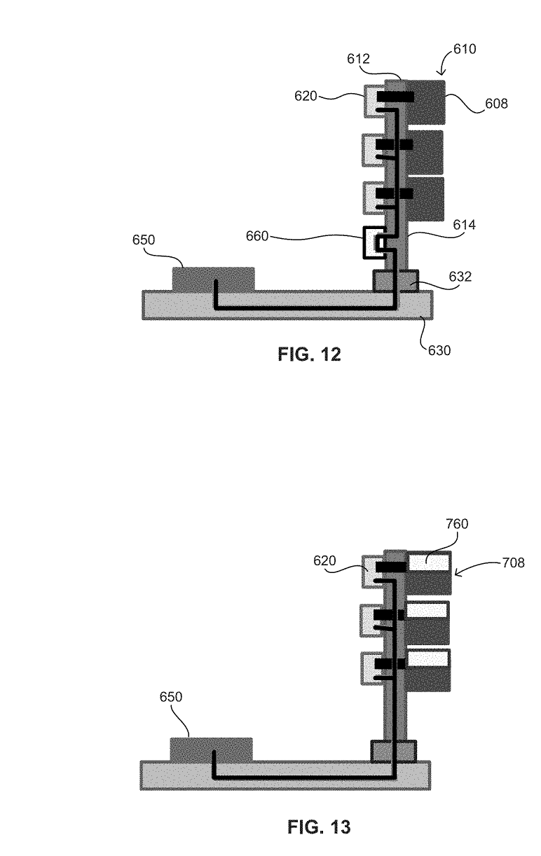

As seen in FIG. 12, in a further variation, a memory module 610 having a substrate such as a module printed circuit board (“PCB”) 612 is coupled, for example, to a motherboard 630 though a socket 632, the module 610 having a plurality of microelectronic packages 608 mounted to a surface 614 of the module PCB. In one example, the memory module 610 provides access to one or more channels and one or more ranks of nonvolatile memory storage through particular forms of microelectronic elements in microelectronic packages 608 similar to those described above. The microelectronic packages can be mounted to the module PCB such that planes parallel to the major surfaces of the microelectronic elements are non-parallel with a plane defined by a major surface 614 of the module PCB. In another example, the memory module 610 may provide access to one or more channels and one or more ranks of dynamic random access memory (“DRAM”) in memory storage arrays of the microelectronic elements in microelectronic packages 608 coupled to the module PCB 612. A plurality of data buffers 620 and/or a registered clock driver (“RCD” not shown) are electrically coupled with the microelectronic packages 608. In this example, one or more repeater assemblies 660 are mounted to the module PCB 612 and are coupled to the data buffers 620 and/or RCD for amplifying signals received from the memory channel control element 650 for delivery to the memory module 610. In addition, signals output from the data buffers or RCD coupled to each microelectronic package are amplified by the one or more repeater assemblies 660 and transmitted in a direction to the memory channel control element 650.

FIG. 13 illustrates a further variation in which repeater assemblies 760 are provided associated with each microelectronic package 708 or coupled within each microelectronic package 708. In this case, each repeater assembly can amplify signals received from the memory channel control element 650 through a data buffer 620 for output to the microelectronic elements of the package 708. Conversely, each repeater assembly can amplify signals received from the microelectronic elements of a package 708 for output to a data buffer 620 and then, in turn, to the memory channel control element 650.

In further variations of any of the above-described microelectronic assemblies, another component may take the place of the repeater assembly, or may be added to the microelectronic assembly in each case. In particular examples, a temperature sensor or a Bluetooth controller can be provided in the assembly, such as can be used for remote monitoring of the microelectronic elements therein. In other examples, an error correction code (“ECC”) encoder/decoder element, or a passives element or “IPOC” (integrated passives on chip element) can be provided for capacitive decoupling of the microelectronic elements in the microelectronic assembly from the external system. In another example, a master-slave arrangement of microelectronic elements can be implemented having a master microelectronic element in place of the repeater assembly, and the slave microelectronic elements provided at the positions where the microelectronic elements are shown.

In another example, a “gearbox” or serializer-deserializer (“SERDES”) component could be provided in the place of the repeater assembly in any of the examples shown above. The modified microelectronic assembly in each case could be used in an example in which a traditional memory channel control element is coupled to a motherboard of the system and is configured to transmit parallel signals to a second SERDES associated with the motherboard. The serial output of the second SERDES, in turn, is coupled with inputs to one or more SERDES devices of the microelectronic assembly, which are then configured to deserialize the received serial signals and distribute them in parallel to the microelectronic elements or the microelectronic packages in the assembly.

Going out from each microelectronic assembly, the SERDES of each microelectronic assembly can be coupled to receive parallel signals from each microelectronic package or microelectronic element. The SERDES of each microelectronic assembly then is coupled to the second SERDES associated with the motherboard so as to transmit the serialized signals from the SERDES outputs from each microelectronic assembly to the second SERDES. The second SERDES, in turn, deserializes the received serial signals into parallel signals which then are output to the memory channel control element.

In a further variation, the SERDES associated with the motherboard could be integrated into the memory channel control element.

Although not specifically shown in the Figures or particularly described in the foregoing, elements in the various Figures and various described embodiments can be combined together in additional variations of the invention.

Although the invention herein has been described with reference to particular embodiments, it is to be understood that these embodiments are merely illustrative of the principles and applications of the various embodiments described herein. It is therefore to be understood that numerous modifications can be made to the illustrative embodiments and that other arrangements can be devised without departing from the spirit and scope of the embodiments as specifically provided or claimed herein.

1. A microelectronic assembly, comprising:
a circuit panel having a plurality of first contacts at a major surface of the circuit panel;
a plurality of microelectronic packages, each microelectronic package having:
a dielectric element having a major surface that defines a first plane, the dielectric element having one or more layers of dielectric material and one or more electrically conductive layers thereon;
a plurality of electrically conductive package terminals disposed at an interconnect region of the dielectric element adjacent an interconnect edge of the dielectric element, the package terminals being electrically coupled with the first contacts;
a plurality of stacked microelectronic elements, each of the microelectronic elements having a respective front face and respective element contacts at the front face which are electrically coupled with the package terminals of the respective microelectronic package through electrically conductive leads extending from the element contacts to the package terminals, each microelectronic element comprising a memory storage array; and
an encapsulant region that contacts the element contacts at the front face of each of the microelectronic elements and that overlies a portion of the major surface of the respective dielectric element, the encapsulant region having a major surface that is substantially parallel to the major surface of the respective dielectric element,
wherein the major surfaces of the dielectric elements and the front faces of the microelectronic elements of the microelectronic packages are oriented parallel with one another and non-parallel with the major surface of the circuit panel,
at least one repeater assembly configured to condition one or more signals received from a memory channel controller including at least one or more signals selected from: an address signal, a command signal, or a data signal,
wherein the microelectronic elements are coupled with the repeater assembly to receive the conditioned signals.

2. The microelectronic assembly of claim 1, wherein the repeater assembly is configured to condition the one or more signals to support greater loads thereon.

3. The microelectronic assembly of claim 2, wherein the repeater assembly is configured to condition the one or more signals by analog amplification without electrically regenerating the one or more signals.

4. (canceled)

5. The microelectronic assembly of claim 1, wherein the at least one repeater assembly has a major surface parallel to the major surfaces of the plurality of packages, and the repeater assembly has a plurality of terminals electrically coupled with the first contacts of the circuit panel.

6. The microelectronic assembly of claim 1, wherein the at least one repeater assembly comprises a plurality of repeater assemblies, each associated with a microelectronic package of the plurality of microelectronic packages, and each repeater assembly electrically coupled between the terminals of the respective microelectronic package and the microelectronic elements of the respective microelectronic package.

7. The microelectronic assembly of claim 1, wherein the at least one repeater assembly is electrically coupled to third contacts of the circuit panel, and a major surface of the at least one repeater assembly is oriented parallel to the major surface of the circuit panel, and the circuit panel is configured to route one or more signals output from the repeater assembly to the first contacts.

8. The microelectronic assembly of claim 7, wherein the first contacts are at a first surface of the circuit panel, and a major surface of the repeater assembly overlies a second surface of the circuit panel opposite from the first surface.

9. The microelectronic assembly of claim 1, wherein the circuit panel has an edge surface extending away from the major surface and a plurality of second contacts adjacent the edge surface, the circuit panel has a second surface opposite from the major surface and a plurality of second contacts at the second surface, the repeater assembly overlying the second surface and electrically coupled with the second contacts, wherein the circuit panel is configured to route signals output from the repeater assembly to the first contacts.

10. The microelectronic assembly of claim 9, wherein a major surface of the repeater assembly is oriented parallel to and overlies the second surface of the circuit panel.

11. The microelectronic assembly of claim 9, wherein the second contacts of the microelectronic assembly are configured to permit the second contacts to be coupled with a plurality of corresponding contacts associated with a second circuit panel external to the microelectronic assembly.

12. The microelectronic assembly of claim 1, wherein the circuit panel has an edge surface extending away from the major surface, and a plurality of second contacts adjacent the edge surface,
wherein the at least one repeater assembly comprises a plurality of repeater assemblies, each associated with a microelectronic package of the plurality of microelectronic packages, each repeater assembly being electrically coupled between the terminals of the respective microelectronic package and the at least one microelectronic element of the respective microelectronic package.

13. The microelectronic assembly of claim 12, wherein the second contacts of the microelectronic assembly are configured for coupling with a plurality of corresponding contacts associated with a second circuit panel external to the microelectronic assembly.

14. A microelectronic assembly, comprising:
a circuit panel having a plurality of first contacts at a major surface of the circuit panel;
a plurality of microelectronic packages each microelectronic package having:
a dielectric element having a major surface that defines a first plane, the dielectric element having one or more layers of dielectric material and one or more electrically conductive layers thereon;
a plurality of electrically conductive package terminals disposed at an interconnect region of the dielectric element adjacent an interconnect edge of the dielectric element, the package terminals being electrically coupled with the first contacts;
a plurality of stacked microelectronic elements, each of the microelectronic elements having a respective front face and respective element contacts at the front face which are electrically coupled with the package terminals of the respective microelectronic package through electrically conductive leads extending from the element contacts to the package terminals, each microelectronic element comprising a memory storage array; and
an encapsulant region that contacts the element contacts at the front face of each of the microelectronic elements and that overlies a portion of the major surface of the respective dielectric element, the encapsulant region having a major surface that is substantially parallel to the major surface of the respective dielectric element,
wherein the major surfaces of the dielectric elements and the front faces of the microelectronic elements of the microelectronic packages are oriented parallel with one another and non-parallel with the major surface of the circuit panel,
at least one repeater assembly configured to condition one or more signals received from a memory channel controller to support greater loads thereon, the one or more signals comprising one or more signals selected from: an address signal, a command signal, or a data signal,
and, wherein the microelectronic elements are coupled with the repeater assembly to receive the conditioned signals, and the repeater assembly is configured to condition the one or more signals by analog amplification without electrically regenerating the one or more signals.

15. (canceled)

16. The microelectronic assembly of claim 14, wherein the at least one repeater assembly comprises a plurality of repeater assemblies, each associated with a microelectronic package of the plurality of microelectronic packages, and each repeater assembly electrically coupled between the terminals of the respective microelectronic package and the microelectronic elements of the respective microelectronic package.

17. The microelectronic assembly of claim 14, wherein the at least one repeater assembly is electrically coupled to third contacts of the circuit panel, and a major surface of the at least one repeater assembly is oriented parallel to the major surface of the circuit panel, and the circuit panel is configured to route one or more signals output from the repeater assembly to the first contacts.

18. A microelectronic module, comprising:
a module circuit board having a plurality of first contacts at a major surface of the module circuit board;
a plurality of microelectronic packages each microelectronic package having:
a dielectric element having a major surface that defines a first plane, the dielectric element having one or more layers of dielectric material and one or more electrically conductive layers thereon;
a plurality of electrically conductive package terminals disposed at an interconnect region of the dielectric element adjacent an interconnect edge of the dielectric element, the package terminals being electrically coupled with the first contacts;
a plurality of stacked microelectronic elements, each of the microelectronic elements having a respective front face and respective element contacts at the front face which are electrically coupled with the package terminals of the respective microelectronic package through electrically conductive leads extending from the element contacts to the package terminals, each microelectronic element comprising a memory storage array; and
an encapsulant region that contacts the element contacts at the front face of each of the microelectronic elements and that overlies a portion of the major surface of the respective dielectric element, the encapsulant region having a major surface that is substantially parallel to the major surface of the respective dielectric element,
wherein the major surfaces of the dielectric elements and the front faces of the microelectronic elements of the microelectronic packages are oriented parallel with one another and non-parallel with the major surface of the module circuit board,
at least one repeater assembly configured to condition one or more signals received from a memory channel controller to support greater loads thereon, the one or more signals comprising one or more signals selected from: an address signal, a command signal, or a data signal,
and, wherein the microelectronic elements are coupled with the repeater assembly to receive the conditioned signals, and the repeater assembly is configured to condition the one or more signals by analog amplification without electrically regenerating the one or more signals.

19. The microelectronic module as claimed in claim 18, wherein the repeater assembly is electrically coupled to receive input from a memory channel control element and to provide output to at least one of: a plurality of data buffers and a registered clock driver (“RCD”), and to receive input from at least one of: the plurality of data buffers and the RCD, and provide output to the memory channel control element.

20. The microelectronic module of claim 18, wherein the at least one repeater assembly has a major surface parallel to the major surfaces of the one or more packages, and the repeater assembly has a plurality of terminals electrically coupled with the first contacts of the circuit panel.

21. The microelectronic assembly of claim 1, wherein the repeater assembly includes a plurality of redrivers configured to amplify magnitudes of signals received at inputs to the redrivers without performing retiming functionality.

22. The microelectronic assembly of claim 1, wherein the repeater assembly includes a plurality of retimers and is configured to regenerate anew signals received at inputs to the retimers.
